(19) United States
(12) Patent Application Publication
(10) Pub. No.: US 2025/0333594 A1
(43) Pub. Date: Oct. 30, 2025

(54) RESIN COMPOSITION

(71) Applicant: NAN YA PLASTICS CORPORATION, Taipei City (TW)

(72) Inventors: Ching-Yao Yuan, Taipei City (TW); Li Yun Chen, Taipei City (TW); Wei-Ru Huang, Taipei City (TW); Hung-Yi Chang, Taipei City (TW); Chia-Lin Liu, Taipei City (TW)

(73) Assignee: NAN YA PLASTICS CORPORATION, Taipei City (TW)

(21) Appl. No.: 18/665,582

(22) Filed: May 16, 2024

(30) Foreign Application Priority Data
Apr. 25, 2024 (TW) 113115423

(51) Int. Cl. C08L 67/00; C08K 7/18; H05K 1/03

(52) U.S. Cl. CPC C08L 67/00; C08K 7/18; H05K 1/0373

(57) ABSTRACT

A resin composition includes an epoxy resin, an active ester compound, an acrylate resin, an inorganic filler material, and an accelerator. The accelerator includes a first compound and a second compound. A curing temperature of the first compound is different from a curing temperature of the second compound, and both the first compound and the second compound are selected from any of a pyridine compound and an imidazole compound.

### CROSS-REFERENCE TO RELATED APPLICATION

This application claims the priority benefit of Taiwan application serial no. 113115423, filed on Apr. 25, 2024. The entirety of the above-mentioned patent application is hereby incorporated by reference herein and made a part of specification.

### BACKGROUND OF THE INVENTION

### Field of the Invention

The invention relates to a resin composition.

### Description of Related Art

In recent years, with the rapid development of integrated circuit (IC) techniques, requirements such as wiring density (L/S) and transmission rate of chips (such as high-speed computing chips) have increased. Moreover, in order to reduce dielectric properties, most current resin compositions are an epoxy resin with an ester cured product. However, this resin composition readily becomes brittle after curing and has a tendency to crack (break).

### SUMMARY OF THE INVENTION

The invention provides a resin composition that has good performance in both electrical properties and crack resistance.

A resin composition of the invention includes an epoxy resin, an active ester compound, an acrylate resin, an inorganic filler material, and an accelerator. The accelerator includes a first compound and a second compound. A curing temperature of the first compound is different from a curing temperature of the second compound, and both the first compound and the second compound are selected from any of a pyridine compound and an imidazole compound.

In an embodiment of the invention, when the first compound is the pyridine compound and the second compound is the imidazole compound, a weight proportion of the first compound in the resin composition is between 0.01 wt % and 0.3 wt %, and a weight proportion of the second compound in the resin composition is between 0.01 wt % and 0.3 wt %.

In an embodiment of the invention, when both the first compound and the second compound are the imidazole compound, a weight proportion of the first compound in the resin composition is between 0.01 wt % and 0.3 wt %, and a weight proportion of the second compound in the resin composition is between 0.01 wt % and 0.3 wt %.

In an embodiment of the invention, a weight proportion of the epoxy resin in the resin composition is between 5 wt % and 15 wt %, a weight proportion of the active ester compound in the resin composition is between 10 wt % and 20 wt %, a weight proportion of the inorganic filler material in the resin composition is greater than 60 wt %, a weight proportion of the acrylate resin in the resin composition is between 1 wt % and 20 wt %, and a weight proportion of the accelerator in the resin composition is between 0.01 wt % and 0.3 wt %.

In an embodiment of the invention, the epoxy resin includes a biphenyl aralkyl epoxy resin, a bisphenol A epoxy resin, or a combination thereof, the active ester compound includes a polyester resin, the acrylate resin includes a methacrylate polyphenylene ether resin, and the inorganic filler material includes spherical silica.

In an embodiment of the invention, a usage amount of the inorganic filler material in the resin composition is greater than usage amounts of the epoxy resin, the active ester compound, the acrylate resin, and the accelerator in the resin composition. In an embodiment of the invention, a usage amount of the accelerator in the resin composition is less than usage amounts of the epoxy resin, the active ester compound, and the acrylate resin in the resin composition.

In an embodiment of the invention, a curing temperature of the first compound is between 60° C. and 100° C., and a curing temperature of the second compound is between 100° C. and 160° C.

In an embodiment of the invention, the pyridine compound includes 4-dimethylaminopyridine.

In an embodiment of the invention, the imidazole compound includes 1-benzyl-2-phenylimidazole, 1-cyanoethyl-2-phenylimidazole, 2-heptadecanyl imidazole, or a combination thereof.

Based on the above, in the invention, the film forming speed (non-one-time film forming) is reduced by using at least two accelerators having different curing temperatures. This allows reactions to occur in different intervals during the continuous heating process of thermal curing, thereby effectively alleviating the cracking (rupture) situation. Moreover, the resin composition including these accelerators still has low dielectric properties. As a result, the resin composition of the invention may have good performance in both electrical properties and crack resistance.

In order to make the aforementioned features and advantages of the disclosure more comprehensible, embodiments accompanied with figures are described in detail below.

### DESCRIPTION OF THE EMBODIMENTS

In the following detailed description, for purposes of illustration and not limitation, exemplary embodiments disclosing specific details are set forth in order to provide a thorough understanding of the various principles of the invention. It will be apparent, however, to one of ordinary skill in the art, having the benefit of this disclosure, that the invention may be practiced in other embodiments that depart from the specific details disclosed herein.

Unless otherwise stated, the term “between” used in this specification to define numerical ranges is intended to cover ranges equal to and between the stated endpoints. For example, if a size range is between a first value and a second value, it means that the size range may cover the first value, the second value, and any value between the first value and the second value.

Unless otherwise defined, all terms (including technical and scientific terms) used herein have the same meaning as commonly understood by those skilled in the art to which this invention belongs.

In the present embodiment, a resin composition includes an epoxy resin, an active ester compound, an acrylate resin, an inorganic filler material, and an accelerator. Furthermore, the accelerator includes a first compound and a second compound, wherein a curing temperature of the first compound is different from a curing temperature of the second compound, and both the first compound and the second compound are selected from any of a pyridine compound and an imidazole compound. Accordingly, in the present embodiment, the film forming speed (non-one-time film forming) is reduced by using at least two accelerators having different curing temperatures (e.g., the curing temperature ranges are not exactly the same). This allows reactions to occur in different intervals during the continuous heating process of thermal curing, thereby effectively alleviating the cracking (rupture) situation. Moreover, the resin composition including these accelerators still has low dielectric properties. As a result, the resin composition of the present embodiment may have good performance in both electrical properties and crack resistance.

In some embodiments, the curing temperature of the first compound is between 60° C. and 100° C., and the curing temperature of the second compound is between 100° C. and 160° C., but the invention is not limited thereto.

In some embodiments, when the first compound is a pyridine compound (such as 4-dimethylaminopyridine, the like, or a combination thereof) and the second compound is an imidazole compound (such as 1-benzyl-2-phenylimidazole, 1-cyanoethyl-2-phenylimidazole, 2-heptadecylimidazole, the like, or a combination thereof), the weight proportion of the first compound in the resin composition is between 0.01 wt % and 0.3 wt % and the weight proportion of the second compound in the resin composition is between 0.01 wt % and 0.3 wt %. In this way, the high reactivity of the pyridine compound may be maintained and the issue of rapid film forming and cracking at lower temperatures may be alleviated, but the invention is not limited thereto.

In some embodiments, when both the first compound and the second compound are imidazole compounds (such as 1-benzyl-2-phenylimidazole, 1-cyanoethyl-2-phenylimidazole, 2-heptadecylimidazole, the like, or a combination thereof), the weight proportion of the first compound in the resin composition is between 0.01 wt % and 0.3 wt %, the weight proportion of the second compound in the resin composition is between 0.01 wt % and 0.3 wt %, but the invention is not limited thereto.

In some embodiments, the weight proportion of the accelerator (such as the total weight of the first compound and the second compound) in the resin composition is between 0.01 wt % and 0.3 wt %, but the invention is not limited thereto.

In some embodiments, the epoxy resin includes a biphenyl aralkyl epoxy resin (such as a naphthylene ether epoxy resin), a bisphenol A epoxy resin, or a combination thereof, wherein the weight proportion of the epoxy resin in the resin composition is between 5 wt % and 15 wt % (for example, 5 wt %, 7 wt %, 10 wt %, 12 wt %, 15 wt %, or any suitable value between 5 wt % and 15 wt %), but the invention is not limited thereto.

In some embodiments, the reactive ester compound includes a polyester resin, wherein the weight proportion of the active ester compound in the resin composition is between 10 wt % and 20 wt % (for example, 10 wt %, 12 wt %, 15 wt %, 17 wt %, 20 wt %, or any suitable value between 10 wt % and 20 wt %), but the invention is not limited thereto.

In some embodiments, the acrylate resin includes a methacrylate polyphenylene ether resin, wherein the weight proportion of acrylate resin in the resin composition is between 1 wt % and 20 wt % (for example, 1 wt %, 3 wt %, 5 wt %, 7 wt %, 15 wt %, 20 wt %, or any suitable value between 1 wt % and 20 wt %), but the invention is not limited thereto.

In some embodiments, the inorganic filler material includes spherical silica, wherein the weight proportion of the inorganic filler material in the resin composition is greater than 60 wt %, but the invention is not limited thereto. Here, the median particle size (D₅₀) of the inorganic filler material may be less than 1 micron or any other suitable value.

In some embodiments, the inorganic filler material is prepared by a synthesis method so that the inorganic filler material contains an epoxy-based or acrylic-based surface modification to improve performance, wherein the synthesis method is, for example, a solid-state synthesis method, but the invention is not limited thereto.

In some embodiments, the purity of the inorganic filler material is greater than or equal to 99%, but the invention is not limited thereto.

In some embodiments, the specific surface area of the inorganic filler material is between 4 m²/g and 6 m²/g to control the contact area with a functional group within a better range to maintain better low dielectric characteristics, for example, Dk is between 3 and 3.3, and Df is less than or equal to 0.003. However, the invention is not limited thereto, and the specific surface area of the inorganic filler material may be determined according to actual design requirements.

In some embodiments, the usage amount of the inorganic filler material in the resin composition is greater than the usage amounts of the epoxy resin, the active ester compound, the acrylate resin, and the accelerator in the resin composition, but the invention is not limited thereto.

In some embodiments, the usage amount of the accelerator in the resin composition is less than the usage amounts of the epoxy resin, the active ester compound, and the acrylate resin in the resin composition, but the invention is not limited thereto.

In some embodiments, the total weight ratio of the epoxy resin, the active ester compound, the acrylic resin, the inorganic filler material, and the accelerator (such as the first compound and the second compound) in the resin composition is 100 wt %, but the invention is not limited thereto.

It should be noted that the resin composition may be regarded as a non-volatile component of a resin composition (varnish form) dissolved in a solvent, but the invention is not limited thereto. Moreover, the resin composition of the invention may be processed into a prepreg and a copper foil substrate (CCL) according to actual design requirements, and the specific implementations listed above are not limitations of the invention.

The following examples and comparative example are given to illustrate the effects of the invention, but the scope of the invention is not limited to the scope of the examples.

The products of each Example and Comparative example were evaluated according to the following method.

Glass transition temperature (Tg) (C): the glass transition temperature Tg (° C.) of the material was measured using a thermomechanical analyzer (TMA) according to the standard test method of ASTM E1545.

Coefficient of thermal expansion (CTE) (x-y plane direction): using a thermomechanical analyzer (TMA), the coefficient of thermal expansion, that is, X-Y CTE (ppm/° C.) of the material in the X-Y plane was measured according to the standard test method of IPC-TM-650 2.4.24. The temperature rising range condition of the test was 25° C. to 150° C.

Dielectric constant Dk/dielectric loss Df: the resin films made using the resin compositions of Table 1 were heated at 200° C. for 90 minutes to form cured films. The cured films were cut into a size of 10 mm in length and 7 mm in width. According to the standard test method of IPC-TM-650 (method 2.5.5.3), the dielectric constant (Dk, ε r) and dielectric loss (dissipation factor, Df, Tan δ) of the material under a 10 GHz signal were measured.

Resin sheet lamination and curing: a glass cloth epoxy resin substrate having a copper foil was prepared as the inner substrate, and both sides were coated with copper lamination (“NPG-180INBK” manufactured by Nan Ya Co., Ltd.), and the surface copper foil of the inner substrate was roughened. Using a vacuum laminator (“V-130” manufactured by Nikko-Material Co., Ltd.), the resin composition and the inner layer substrate were bonded via the vacuum laminator. The conditions were: after the pressure was reduced to 1 hPa or less for 30 seconds, lamination was performed for 60 seconds at a temperature of 100° C./pressure of 100 N. Subsequently, the product was heated in an oven at 130° C. for 30 minutes, and then moved to an oven at 165° C. for 30 minutes. The resin composition was cured by the above heating, and a substrate A was obtained.

De-smear treatment: in order to roughen the cured resin sheet substrate, the substrate A was immersed in Sweller 7810 manufactured by DuPont at 70° C. for 10 minutes. Next, the substrate A was immersed in Promotor 7820 manufactured by DuPont at 85° C. for 10 minutes. Lastly, the substrate A was immersed in Neutralizer 7831 manufactured by DuPont at 40° C. for 5 minutes to obtain an evaluation substrate B after the de-smear treatment.

Crack resistance: after the de-smear process was performed on the substrate A, the evaluation substrate B was obtained. The evaluation substrate B was observed. ⊚: no cracks occurred. X: there were cracks greater than 0.2 cm on the surface.

### Examples 1 to 5, Comparative Example 1

The resin compositions shown in Table 1 were dissolved in a solvent (toluene, methyl ethyl ketone, cyclohexanone), and the mixture was coated on a support (PET film) using a mouth-mode coater. After drying to form a film layer, properties such as glass transition temperature, coefficient of thermal expansion, dielectric constant, and dielectric loss were evaluated, and the crack resistance test was performed in the above way, and the results are shown in Table 1. After comparing the results of Example 1 to Example 5 and Comparative example 1 of Table 1, the following conclusions may be drawn: compared with Comparative example 1, Examples 1 to 5 using at least two accelerators having different curing temperatures had better performance in both electrical properties and crack resistance.

TABLE 1

| | Comparative | | | | | |
|---|---|---|---|---|---|---|
| | example | Example | | | | |
| | 1 | 1 | 2 | 3 | 4 | 5 |
| Epoxy resin (NC3500) | 6.25 | 6.25 | 6.25 | 6.25 | 6.25 | 6.25 |
| (parts by mass) | | | | | | |
| Epoxy resin (NPEL-170) | 6.25 | 6.25 | 6.25 | 6.25 | 6.25 | 6.25 |
| (parts by mass) | | | | | | |
| Active ester compound (HPC-8150) | 18.85 | 18.85 | 18.85 | 18.85 | 18.85 | 18.85 |
| (parts by mass) | | | | | | |
| First filler of inorganic filler material | 100 | 100 | 100 | 100 | 100 | 100 |
| (EQK0610-SMS, | | | | | | |
| D50 = 0.6 microns/Third Age Technology) | | | | | | |
| (parts by mass) | | | | | | |
| Acrylic resin (SA-9000) (parts by mass) | 3.6 | 3.6 | 3.6 | 3.6 | 3.6 | 3.6 |
| Accelerator | 0.2 | 0.1 | 0.1 | 0.1 | 0 | 0 |
| (DMAP, curing temperature 60° C. | | | | | | |
| to 100° C.) (parts by mass) | | | | | | |
| Accelerator | 0 | 0.2 | 0 | 0 | 0.2 | 0.2 |
| (1B2PZ, curing temperature 100° C. | | | | | | |
| to 150° C.) (parts by mass) | | | | | | |
| Accelerator | 0 | 0 | 0.2 | 0 | 0.2 | 0 |
| (2PZ-CN, curing temperature 120° C. | | | | | | |
| to 150° C.) (parts by mass) | | | | | | |
| Accelerator | 0 | 0 | 0 | 0.2 | 0 | 0.2 |
| (C17Z, curing temperature 100° C. | | | | | | |
| to 140° C.) (parts by mass) | | | | | | |
| Glass transition temperature (° C.) | 172 | 170 | 168 | 168 | 170 | 168 |
| X-Y coefficient of thermal expansion | 13.55 | 14.2 | 14.5 | 13.8 | 14.2 | 13.6 |
| (25° C. to 150° C.) (ppm/° C.) | | | | | | |
| Dk/Df (10 GHz) | 3.3/0.0028 | 3.2/0.0027 | 3.3/0.0027 | 3.3/0.0028 | 3.3/0.0027 | 3.3/0.0027 |
| Crack resistance | X | ⊚ | ⊚ | ⊚ | ⊚ | ⊚ |

Based on the above, in the invention, the film forming speed (non-one-time film forming) is reduced by using at least two accelerators having different curing temperatures. This allows reactions to occur in different intervals during the continuous heating process of thermal curing, thereby effectively alleviating the cracking (rupture) situation. Moreover, the resin composition including these accelerators still has low dielectric properties. As a result, the resin composition of the invention may have good performance in both electrical properties and crack resistance.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A resin composition, comprising:
an epoxy resin;
an active ester compound;
an acrylic resin;
an inorganic filler material; and
accelerator comprising a first compound and a second compound, wherein a curing temperature of the first compound is different from a curing temperature of the second compound, and both the first compound and the second compound are selected from any of a pyridine compound and an imidazole compound.

2. The resin composition of claim 1, wherein when the first compound is the pyridine compound and the second compound is the imidazole compound, a weight proportion of the first compound in the resin composition is between 0.01 wt % and 0.3 wt %, and a weight proportion of the second compound in the resin composition is between 0.01 wt % and 0.3 wt %.

3. The resin composition of claim 1, wherein when both the first compound and the second compound are the imidazole compound, a weight proportion of the first compound in the resin composition is between 0.01 wt % and 0.3 wt %, and a weight proportion of the second compound in the resin composition is between 0.01 wt % and 0.3 wt %.

4. The resin composition of claim 1, wherein a weight proportion of the epoxy resin in the resin composition is between 5 wt % and 15 wt %, a weight proportion of the active ester compound in the resin composition is between 10 wt % and 20 wt %, a weight proportion of the inorganic filler material in the resin composition is greater than 60 wt %, a weight proportion of the acrylate resin in the resin composition is between 1 wt % and 20 wt %, and a weight proportion of the accelerator in the resin composition is between 0.01 wt % and 0.3 wt %.

5. The resin composition of claim 1, wherein the epoxy resin comprises a biphenyl aralkyl epoxy resin, a bisphenol A epoxy resin, or a combination thereof, the active ester compound comprises a polyester resin, the acrylate resin comprises a methacrylate polyphenylene ether resin, and the inorganic filler material comprises spherical silica.

6. The resin composition of claim 1, wherein a usage amount of the inorganic filler material in the resin composition is greater than usage amounts of the epoxy resin, the active ester compound, the acrylate resin, and the accelerator in the resin composition.

7. The resin composition of claim 1, wherein a usage amount of the accelerator in the resin composition is less than usage amounts of the epoxy resin, the active ester compound, and the acrylate resin in the resin composition.

8. The resin composition of claim 1, wherein a curing temperature of the first compound is between 60° C. and 100° C., and a curing temperature of the second compound is between 100° C. and 160° C.

9. The resin composition of claim 1, wherein the pyridine compound comprises 4-dimethylaminopyridine.

10. The resin composition of claim 1, wherein the imidazole compound comprises 1-benzyl-2-phenylimidazole, 1-cyanoethyl-2-phenylimidazole, 2-heptadecanyl imidazole, or a combination thereof.
